(19) United States
(12) Patent Application Publication
(10) Pub. No.: US 2005/0181538 A1
(43) Pub. Date: Aug. 18, 2005

(54) Semiconductor device for wire-bonding and flip-chip bonding package and manufacturing method thereof

(75) Inventor: Mon-Chin Tsai, Kaohsiung City (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaoshiung (TW)

(21) Appl. No.: 10/876,581

(22) Filed: Jun. 28, 2004

(30) Foreign Application Priority Data
Feb. 13, 2004 (TW) 093103550

(51) Int. Cl. H01L 21/00; H01L 21/44; H01L 21/48; H01L 21/50

(52) U.S. Cl. 438/108; 438/51; 438/678

(57) ABSTRACT

A manufacturing method of a semiconductor device for a wire-bonding and flip-chip bonding package mainly comprises the following steps. First, a chip having a plurality of bonding pads and a passivation layer exposing the bonding pads is provided. Next, an under bump metallurgy layer having an aluminum layer, a nickel-vanadium layer and a copper layer is formed on each of the bonding pads. Then, a portion of the copper layer and the nickel-vanadium layer formed over some of the bonding pads is removed so as to leave a portion of the copper layer and the nickel-vanadium layer remained over some of the bonding pads to form patterned copper layers and patterned nickel-vanadium layers. Next, a plurality of solder bumps are formed on the patterned copper layers. Finally, a reflowing process is performed to have the solder bumps secured to the patterned copper layers. In addition, a semiconductor device formed by the manufacturing method is provided.

### BACKGROUND OF THE INVENTION

1. Field of Invention

This invention relates to a semiconductor device for a wire-bonding and flip-chip bonding package. More particularly, the present invention is related to a semiconductor device for simplifying the manufacturing process and reducing consumed materials. Moreover, this invention also provides a manufacturing method of the semiconductor device thereof.

2. Related Art

In this information explosion age, integrated circuits products are used almost everywhere in our daily life. As fabricating technique continue to improve, electronic products having powerful functions, personalized performance and a higher degree of complexity are produced. Nowadays, most electronic products are relatively light and have a compact body. Hence, in semiconductor production, various types of high-density semiconductor packages, for example ball grid array package (BGA), chip-scale package (CSP), multi-chips module package (MCM) and flip chip package (F/C), have been developed.

However, as mentioned above, flip chip is one of the most commonly used techniques for forming an integrated circuit package. Compared with a wire-bonding package or a tape automated bonding (TAB) package, a flip-chip package has a shorter electrical path on average and has a better overall electrical performance. In said flip-chip package, the bonding pads on a chip and the contacts on a substrate are connected together through a plurality of bumps formed by the method of bumping process. It should be noted that there are further patterned under bump metallurgy layers disposed on the bonding pads of the chip to be regarded as a connection medium for connecting to the bumps and enhancing the mechanical strength of the connection of the chip to the substrate after said chip is attached to the substrate.

However, as well-know, the semiconductor device utilized for a wire-boding and flip-chip bonding package is mainly formed by the method of providing a wafer having a plurality of chips wherein each chip has bonding pads, forming a plurality of patterned under bump metallurgy layers on the bonding pads respectively, disposing another patterned barrier layers and patterned wetting layers on some of the patterned under bump metallurgy layers for wire-bonding, forming a plurality of bumps or solder balls on the residual patterned under bump metallurgy layers without the patterned barrier layers and patterned wetting layers disposed thereon and then sawing the wafer into a plurality of chips with bumps formed thereon for flip-chip bonding to another chips. As mentioned above, when the bonding pads are aluminum pads, each of the patterned under bump metallurgy layers usually is usually made of an aluminum layer, a nickel-vanadium layer and a copper layer in sequence; and the patterned barrier layer and the patterned wetting layer for wire-bonding are a nickel layer and a gold layer respectively.

Referring to FIG. 1 and FIG. 2, which illustrate partially enlarged cross-sectional views showing the progression of steps for forming a conventional semiconductor device. The manufacturing method of forming such conventional semiconductor device for a wire-bonding and flip-chip bonding package mainly comprises the following steps. Firstly, there is a wafer having a plurality of chips 100 (only one chip 100 is shown) provided and each chip 100 has a plurality of bonding pads 102 exposed out of a passivation layer 104 formed above the chip 100. Next, a plurality of patterned under bump metallurgy layers 106 are disposed above the bonding pads 102 respectively. Therein, when the bonding pads 102 are aluminum pads, each of the patterned under bump metallurgy layers is made of an aluminum layer, a nickel-vanadium layer and a copper layer sequentially formed over the bonding pads 102 through the methods of sputtering or electro-less plating metal materials, regarded as an under bump metallurgy layer, above the chip and patterning the metal materials to form the patterned under bump metallurgy layers through photo-masks and etching process. Afterwards, a plurality of nickel layers 107a and gold layers 107b are sequentially formed on some of the patterned under bump metallurgy layers 106. Then, a photo-resist layer 109 covers the chip 100 to form openings 109a to expose the patterned under bump metallurgy layers 106 not covered by the nickel layers 107a and the gold layers 107b. Then, the openings 109a are filled with solder material 110 to form a plurality of bumps. Finally, a reflowing process is performed to have the bumps attached securely to the patterned under bump metallurgy layer 106 not covered the nickel layers 107a and the gold layers 107b as shown in FIG. 2.

As mentioned above, the under bump metallurgy is patterned before the solder material filled in the openings of the photo-resist layer, the solder material shall be disposed above the under bump metallurgy layer through the method of screen-printing. And when the under bump metallurgy layer is patterned after the solder material filled in the openings of the photo-resist layer, the solder material can be disposed above the under bump metallurgy layer through the method of plating. However, no matter the screen-printing method or the plating method is performed, it is a conventional bumping process. Accordingly, such method will not be further described here.

Because the semiconductor device for a wire-bonding and flip-chip bonding package is shown as mentioned above, it is necessary to form a nickel layer and a gold layer on the patterned or un-patterned under bump metallurgy layer for wire-bonding process. Accordingly, the manufacturing process becomes complex and more and more material are consumed and wasted.

Therefore, providing another method for forming a semiconductor device for a wire-bonding and flip-chip bonding package to solve the mentioned-above disadvantages is the most important task in this invention.

### SUMMARY OF THE INVENTION

In view of the above-mentioned problems, this invention is to provide a manufacturing method for forming a semiconductor device for a wire-bonding and flip-chip bonding package so as to simplify the process and reducing the consumed material. Moreover, this invention also provides a semiconductor device manufactured according to the above-mentioned manufacturing method.

To achieve these and other advantages and in accordance with the purpose of the invention, as embodied and broadly described herein, the invention provides a manufacturing method of a semiconductor device for a wire-bonding and flip-chip bonding. The manufacturing method mainly comprises the following steps. Firstly, there is a wafer having a plurality of chips provided and each chip has a plurality of bonding pads exposed out of a passivation layer formed above the chip. Next, a plurality of patterned under bump metallurgy layer are disposed above the bonding pads. Therein, usually, each of the patterned under bump metallurgy layers comprises a patterned adhesive layer, a patterned barrier layer and a patterned wetting layer sequentially formed over the bonding pad through the methods of sputtering or electro-less plating metal materials, which is regarded as an under bump metallurgy layer, above the chip and patterning the metal materials to form the patterned under bump metallurgy layers through photo-mask and etching process. Afterwards, some of the patterned wetting layers and the patterned barrier layers are removed to expose some of the patterned adhesive layers for wire bonding. Then, a plurality of bumps are formed on the un-removed patterned wetting layers of the patterned under bump metallurgy layer. Finally, a reflowing process is performed to have the bumps attached to the patterned wetting layer of the patterned under bump metallurgy layer. To be noted, generally, when the bonding pads are aluminum pads, the patterned adhesive layer, the patterned barrier layer and the patterned wetting layer are made of aluminum, nickel-vanadium and copper respectively.

Furthermore, this invention also provides a semiconductor device for a wire-bonding and flip-chip bonding package according to the manufacturing method as mentioned above. The semiconductor device mainly comprises a chip and a plurality of bumps. Therein, the chip has an active surface, a passivation layer, a plurality of bonding pads, and a plurality of patterned under bump metallurgy layers; and the patterned under bump metallurgy layers are formed on the bonding pads. To be noted, some of the patterned under bump metallurgy layer is made of a patterned adhesive layer for wire-bonding and the others are made of a patterned adhesive layer, a patterned barrier layer and a patterned wetting layer sequentially formed on the bonding pads for forming bumps thereon for flip-chip bonding.

As mentioned above, when the bonding pad is made of aluminum and the adhesive layer is made of aluminum, the gold wires can be directly wire-bonded to the adhesive layer. Accordingly, this invention is more applicable to the semiconductor device having a chip with aluminum pads. However, when the bonding pads are made of copper, the patterned adhesive layer is made of titanium. Accordingly, when a portion of the patterned barrier layers and the patterned wetting layers are removed to expose some of the patterned adhesive layers, it is usually to take the titanium layer as the patterned adhesive layer for the gold wires bonded thereto or to provide another aluminum layer disposed on the titanium layer for the gold wires bonded thereto.

It is to be understood that both the foregoing general description and the following detailed description are exemplary, and are intended to provide further explanation of the invention as claimed.

### BRIEF DESCRIPTION OF THE DRAWINGS

The invention will become more fully understood from the detailed description given herein below illustrations only, and thus are not limitative of the present invention, and wherein:

FIGS. 1 to 2 are partially enlarged cross-sectional views showing the progression of steps for forming a conventional semiconductor device for wire-bonding and flip-chip bonding;

FIG. 3 illustrates a partially cross-sectional view of the semiconductor device for wire-bonding and flip-chip bonding package according to the preferred embodiment;

FIGS. 4 to 8 are partially enlarged cross-sectional views showing the progression of steps for forming a semiconductor device according to the preferred embodiment of this invention as shown in FIG. 3; and

FIGS. 9 to 13 are partially enlarged cross-sectional views showing another progression of steps for forming a semiconductor device according to the preferred embodiment of this invention as shown in FIG. 3.

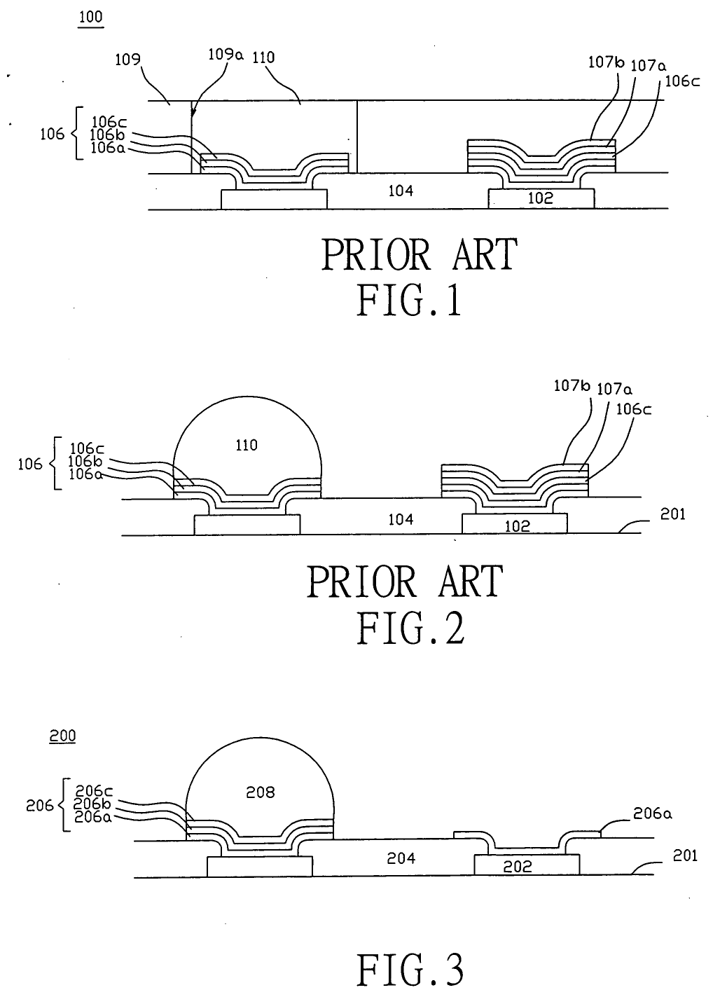

### DETAILED DESCRIPTION OF THE INVENTION

The semiconductor device for a wire-bonding and flip-chip bonding package according to the preferred embodiments of this invention and the manufacturing method thereof will be described herein below with reference to the accompanying drawings, wherein the same reference numbers are used in the drawings and the description to refer to the same or like parts.

FIG. 3 is partially enlarged cross-sectional views showing the semiconductor device for a wire-bonding and flip-chip bonding package according to the preferred embodiment.

As shown in FIG. 3, it illustrates a partially enlarged cross-sectional view of a semiconductor device 200. The semiconductor device 200 mainly comprises a chip and bumps 208. Therein the chip has an active surface 201, a plurality of bonding pads 202 and a passivation layer 204 and a plurality of patterned under bump metallurgy layers 206 formed on the bonding pads 202. Therein, the passivation layer 204 is disposed above the active surface 201 and exposes the bonding pads 202; and one of the patterned under bump metallurgy layers 206 is made of a patterned adhesive layer 206a for wire-bonding and one of the patterned under bump metallurgy layer 206 is made of a patterned adhesive layer 206a, a patterned barrier layer 206b and a patterned wetting layer 206c sequentially formed on the bonding pads 202 for forming bumps 208 thereon for flip-chip bonding to a substrate or another semiconductor device.

To be noted, when the bonding pad 202 is made of aluminum and the patterned adhesive layer 206a is made of aluminum, the gold wires can be directly wire-bonded to the patterned adhesive layer 206a. Moreover, when the bonding pads 202 are made of copper, the patterned adhesive layer 206a is made of titanium. And when only the patterned adhesive layer 206a is formed on the bonding pad 202, it is usually to take the titanium layer as the patterned adhesive layer for the gold wires bonded thereto or to provide another aluminum layer or a gold layer disposed on the titanium layer for the gold wires bonded thereto.

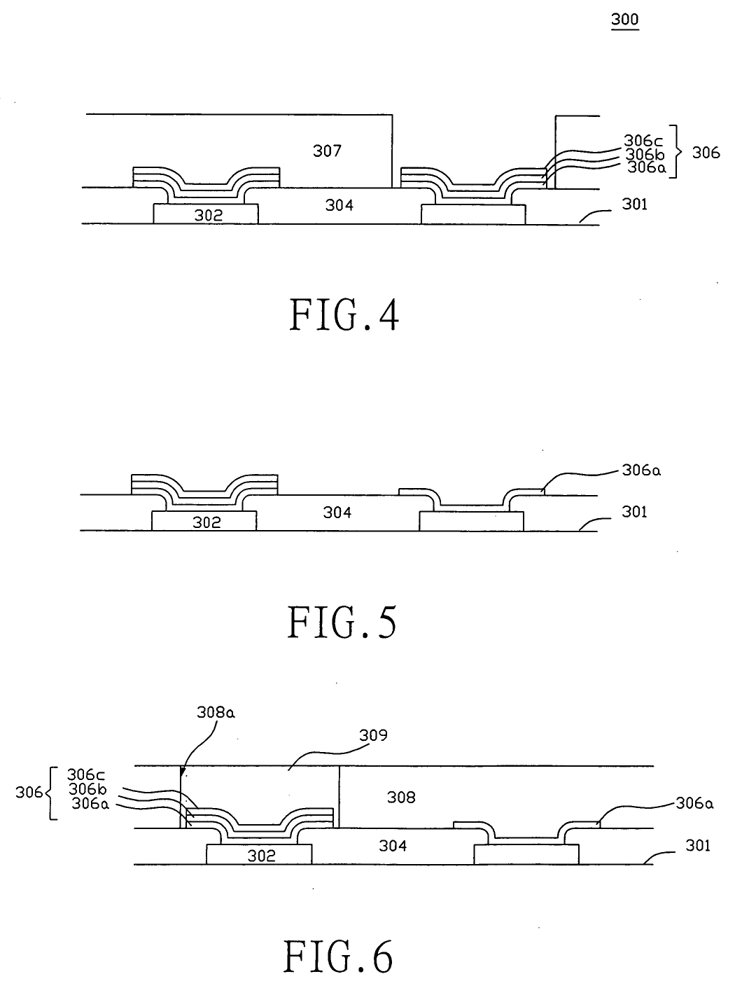

Next, referring to the drawings as shown from FIG. 4 to FIG. 7, which illustrate partially enlarged cross-sectional views showing the progression of steps for forming a semiconductor device according to the preferred embodiment of this invention as shown above.

Firstly, referring to FIG. 4, a chip 300 is provided. Therein, the chip 300 has a plurality of bonding pads 302 and a passivation layer 304 formed above the active surface 301 of the chip 300. Therein, the passivation layer 304 exposes the bonding pads 302.

Next, referring to FIG. 4 again, the patterned under bump metallurgy layers 306 is formed on the bonding pads 302. To be noted, each of the patterned under bump metallurgy layers is made of a patterned adhesive layer 306a, a patterned barrier layer 306b and a patterned wetting layer 306c sequentially formed on the bonding pad 302. Therein, the patterned under bump metallurgy layers 306 can be formed by the method of sputtering or electro-less plating metal materials, regarded as an under bump metallurgy layer, above the chip 300 and patterning the metal materials to complete forming the patterned under bump metallurgy layers 306 through photo-masks and etching process so as to have the patterned under bump metallurgy layers 306 formed on the bonding pads 302. Then, referring to FIG. 4 again, another photo-mask 307 is formed above the chip 300 to expose one of the patterned under bump metallurgy layer 306 disposed over the bonding pad 302. Next, a suitable etchant is taken to remove the patterned wetting layer 306c and the patterned barrier layer 306b not covered by the photo-mask so as to leave the patterned adhesive layer 306a on the bonding pad 302. Afterwards, the photo-mask 307 is removed.

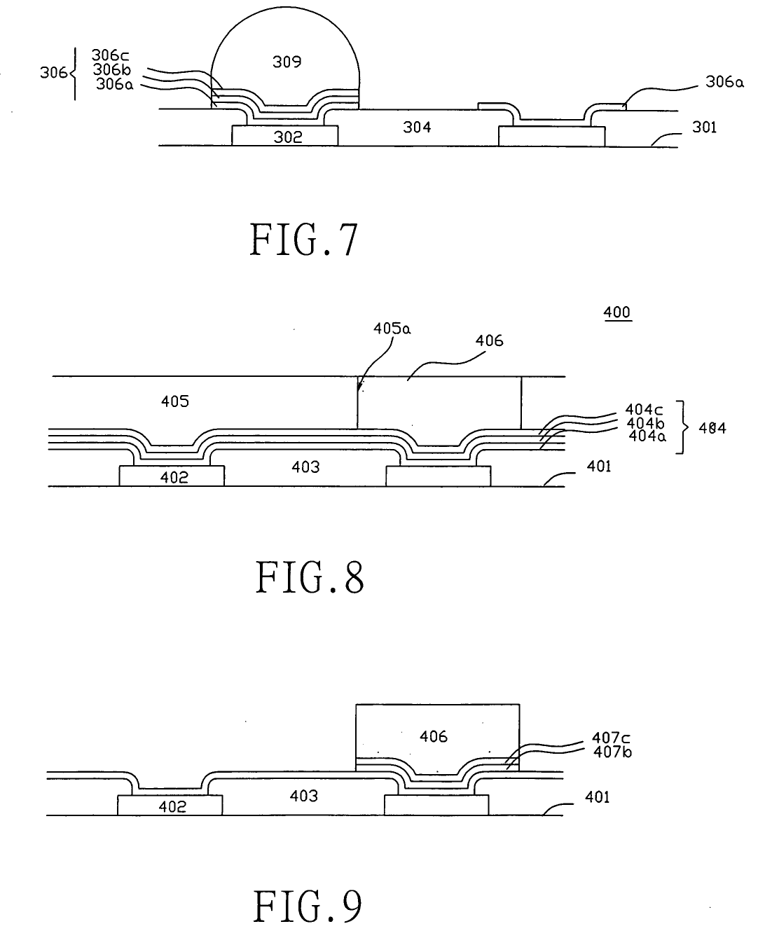

Then, referring to FIG. 6, another photo-mask 308 is disposed above the chip 300 to form a plurality of openings 308a to expose the patterned under bump metallurgy layers 306 with the patterned wetting layer 306c and the patterned barrier layers 306b therein. Afterwards, a solder material is filled in the openings 308a to form a plurality of solder bumps 309. Finally, the photo-mask 308 is removed and a reflowing process is performed to have the solder bumps 310 attached securely to the patterned under bump metallurgy layer 306 as shown in FIG. 7.

As mentioned above, the under bump metallurgy layer 306 is patterned, the solder material 309 is disposed above the patterned under bump metallurgy layer 306 through the method of screen-printing. And when the under bump metallurgy layer is un-patterned, the solder material can be disposed above the under bump metallurgy layer through the method of plating and then the under bump metallurgy layer can be then patterned by taking the bumps as mask to remove the barrier layer and the wetting layer of the under bump metallurgy layer to leave the adhesive layer for wires bonded thereto. However, no matter the screen-printing method or the plating method is performed, such conventional bumping process can be performed to form said semiconductor device for wire-bonding and flip-chip bonding.

As shown from FIG. 8 to FIG. 13, which illustrate the manufacturing method of said semiconductor device by a bump-plating process. Firstly, referring to FIG. 8, a chip 400 is provided. Therein, the chip 400 has a plurality of bonding pads 402 and a passivation layer 404 formed above the active surface 401 of the chip 400. Therein, the passivation layer 404 exposes the bonding pads 402.

Next, referring to FIG. 8 again, an under bump metallurgy layer 404 is formed on the bonding pads 402. To be noted, the under bump metallurgy layer 404 is made of an adhesive layer 404a, a barrier layer 404b and a wetting layer 404c sequentially formed on the bonding pads 402. Therein, the under bump metallurgy layer 404 as shown above can be formed by the method of sputtering or electro-less plating metal materials above the chip 400. Next, a photo-mask 405 is disposed above the under bump metallurgy layer 404 to form a plurality of openings 405a to expose a portion of the wetting layer 404c. Then, a solder material is filled in the openings 405a to form a plurality of solder bumps 406. When the solder bumps 406 are formed by the method of plating, the photo-mask 405 can be then removed so as to take the bumps 406 as etching masks to remove a portion of the wetting layer 404c and the barrier layer 404b not covered by the bumps 406 to form a patterned wetting layer 407c and a patterned barrier layer 407b.

Next, referring to FIG. 10, there is provided another photo-mask 410 formed above the chip 400 as shown in FIG. 10 and patterned the photo-mask 410 through the methods of photolithography and etching to dispose the patterned photo-mask 411 on the adhesive layer 404a over the bonding pads, which is not covered by the solder bumps 406. Then, the patterned photo-mask 411 and the solder bumps 406 are taken as masks to pattern the adhesive layer 404a to form patterned adhesive layers 407a as shown in FIG. 11 and FIG. 12. Finally, the patterned photo-mask 411 is removed and a reflowing process is performed to have the solder bumps 406 attached securely to the patterned under bump metallurgy 407 layers so as to form the semiconductor device by taking the patterned adhesive layers 407a for wire-bonding thereto and by taking the patterned under bump metallurgy layers for flip-chip bonding thereto.

As mentioned above, when the bonding pad is made of aluminum and the adhesive layer is made of aluminum, the gold wires can be directly wire-bonded to the adhesive layer. Accordingly, this invention is more applicable to the semiconductor device having a chip with aluminum pads. However, when the bonding pads are made of copper, the patterned adhesive layer is made of titanium. And when some of the patterned barrier layers and the patterned wetting layer are removed to expose the patterned adhesive layer only, it is usually to take the titanium layer as the patterned adhesive layer for the gold wires bonded thereto or to provide another aluminum layer or a gold layer disposed on the titanium layer for the gold wires bonded thereto.

When the semiconductor device for wire-bonding and flip-chip bonding packages formed according to the preferred embodiments as mentioned above, it is unnecessary to form a nickel layer and a gold layer on the patterned under bump metallurgy layers for wire-bonding. Accordingly, the manufacturing process becomes simple and more and more material will not consumed and wasted.

Although the invention has been described in considerable detail with reference to certain preferred embodiments, it will be appreciated and understood that various changes and modifications may be made without departing from the spirit and scope of the invention as defined in the appended claims.

1. A manufacturing method of a semiconductor device, comprising:
providing a chip, the chip having a passivation layer and a plurality of bonding pads, wherein the passivation layer exposes the bonding pads;
forming patterned under bump metallurgy layers on the bonding pads, wherein each of the patterned under bump metallurgy layers comprises a patterned adhesive layer, a patterned barrier layer and a patterned wetting layer sequentially disposed on the bonding pads;
removing the patterned wetting layers and the patterned barrier layers to expose one of the patterned adhesive layers; and
forming a plurality of bumps on the patterned wetting layers remained over the bonding pads.

2. The method of claim 1, wherein each of the patterned adhesive layer is an aluminum layer.

3. The method of claim 1, wherein each of the patterned adhesive layer is a titanium layer.

4. The method of claim 1, wherein the bumps are solder bumps.

5. The method of claim 1, further comprising the step of performing a reflowing process to have the bumps attached securely to the patterned wetting layers located over the bonding pads.

6. The method of claim 1, wherein each of the patterned barrier layer is a nickel-vanadium layer.

7. The method of claim 1, wherein each of the patterned wetting layer is a copper layer.

8. The method of claim 3, further forming a gold layer on the patterned adhesive layer not covered by the bumps.

9. The method of claim 3, further forming an aluminum layer on the patterned adhesive layer not covered by the bumps.

10. A manufacturing method of a semiconductor device, comprising:
providing a chip, the chip having a passivation layer and a plurality of bonding pads, wherein the passivation layer exposes the bonding pads;
forming an under bump metallurgy layer on the bonding pads, wherein the under bump metallurgy layer comprises an adhesive layer, a barrier layer and a wetting layer sequentially disposed on the bonding pads;
forming a bump on the under bump metallurgy layer located over one of the bonding pads;
removing the wetting layer and the barrier layer not covered by the bump to expose the adhesive layer and form a patterned wetting layer and a patterned barrier layer;
forming a photo-mask on the adhesive layer located over the bonding pads; and
removing the adhesive layer not covered by the photo-mask and the bumps to form a plurality of patterned adhesive layers.

11. The method of claim 10, wherein each of the patterned adhesive layer is an aluminum layer.

12. The method of claim 10, wherein each of the patterned adhesive layer is a titanium layer.

13. The method of claim 10, wherein the bumps are solder bumps.

14. The method of claim 10, further comprising the step of performing a reflowing process to have the bumps attached securely to the patterned wetting layer.

15. The method of claim 10, wherein the barrier layer is a nickel-vanadium layer.

16. The method of claim 10, wherein the wetting layer is a copper layer.

17. The method of claim 12, further forming a gold layer on each of the patterned adhesive layers not covered by the bumps.

18. The method of claim 12, further forming an aluminum layer on each of the patterned adhesive layers not covered by the bumps.

19. The method of claim 14, further comprising the step of removing the photo-mask before the step of performing the reflowing process.

20. A semiconductor device for a wire-bonding and flip-chip bonding package, comprising:
a chip, the chip having an active surface, a passivation layer, a plurality of bonding pads, wherein the passivation layer covers the active surface and exposes the bonding pads;
a plurality of patterned adhesive layers, each of the patterned adhesive layers formed on each of the bonding pads respectively;
a patterned barrier layer formed on one of the patterned adhesive layers located over the bonding pads;
a patterned wetting layer formed on the patterned barrier layer; and
a bump formed on the patterned wetting layer located over the patterned barrier layer and the patterned wetting layer.

21. The semiconductor device of claim 20, wherein each of the patterned adhesive layer is an aluminum layer.

22. The semiconductor device of claim 20, wherein each of the patterned adhesive layer is a titanium layer.

23. The semiconductor device of claim 20, wherein the bumps are solder bumps.

24. The semiconductor device of claim 20, wherein the patterned barrier layer is a nickel-vanadium layer.

25. The semiconductor device of claim 20, wherein the patterned wetting layer is a copper layer.

26. The semiconductor device of claim 22, further has a gold layer formed on each of the patterned adhesive layers not covered by the bump.

27. The semiconductor device of claim 22, further has an aluminum layer formed on each of the patterned adhesive layers not covered by the bump.
